(19) United States
(12) Patent Application Publication
(10) Pub. No.: US 2024/0406640 A1
(43) Pub. Date: Dec. 5, 2024

(54) OVER-THE-SINK DRYING ELEMENT

(71) Applicant: Dorai Home, Inc., West Valley City, UT (US)

(72) Inventors: Jason Klug, Salt Lake City, UT (US); Isabella Gonos, Salt Lake City, UT (US); Caroline Spytman, Salt Lake City, UT (US)

(73) Assignee: Dorai Home, Inc., West Valley City, UT (US)

(21) Appl. No.: 18/801,567

(22) Filed: Aug. 12, 2024

Related U.S. Application Data
(63) Continuation-in-part of application No. 18/528,733, filed on Dec. 4, 2023.
Application No. 18/528,733 is a continuation of application No. 16/852,298, filed on Apr. 17, 2020, now Pat. No. 10,924,867.
(60) Provisional application No. 63/562,705, filed on Mar. 8, 2024.
(60) Provisional application No. 63/532,294, filed on Aug. 11, 2023.

(51) Int. Cl. H04R 19/04; B81B 7/00; H04R 1/04; H04R 1/08; H04R 3/06; H04R 19/00

(52) U.S. Cl. CPC H04R 19/04; B81B 7/0019; B81B 7/0025; H04R 1/04; H04R 19/005; B81B 2201/0257; B81B 2207/012; B81C 2203/0109; B81C 2203/0792; H04R 1/086; H04R 3/06; H04R 2201/003

(57) ABSTRACT

A drying implement may include a first portion having a diatomaceous earth slab and a resilient slab covering, and a second portion that is coupled to the first panel. The resilient slab covering may include a mesh of openings that allow water from an article placed on the resilient slab covering to drip through the mesh of openings, onto the diatomaceous earth slab. The second panel may include a plurality of cross pieces that are overmolded with a resilient second covering.

### CROSS-REFERENCE TO RELATED APPLICATIONS

This application is a continuation-in-part of U.S. patent application Ser. No. 18/528,733, titled “Absorptive Drying Element,” filed Dec. 4, 2023; which is a continuation of U.S. patent application Ser. No. 16/852,208, titled “Absorptive Drying Element,” filed Apr. 17, 2020, now U.S. Pat. No. 11,832,777; which claims priority to U.S. Provisional Patent Application 62/836,583, titled “Absorptive Drying Element,” filed Apr. 19, 2019. This application further claims priority to U.S. Provisional Patent Application 63/532,294, titled “Drying Element,” filed Aug. 11, 2023, and U.S. Provisional Patent Application 63/562,705, titled “Drying Element,” filed Mar. 8, 2024. This application incorporates the entire contents of the foregoing applications by reference.

### BACKGROUND

FIG. 1A illustrates two conventional drying racks 1a and 1b which are generally composed either of rubber or plastic polymer (see 1a) or often polymer coated metal wires (see 1b). In use, a conventional drain tray 10 is positioned beneath the racks 1a and 1b and generally includes a central platform area 13, bounded by raised sidewalls 11, on which the racks 1a and 1b are supported. The water dripping from the racked dishes collects upon the platform area 13 of the drain tray 2, out of contact with the dishes, thereby accelerating the draining and drying of the dishes. Some drain trays 10 in common use provide an outlet channel 12 at one end of the platform area 13. The outlet channel 12, or groove, is often directed over a sink. In this way excess water collected by the drain tray 10 can be diverted into the sink. Other drain trays 10 may merely collect the water in the platform area 13, for eventual disposition by way of evaporation or manual emptying. Such conventional drying racks 1a and 1b are bulky an unappealing in appearance.

Referring to FIG. 1B, a conventional drying mat for kitchenware can include a conventional dish towel. The traditional drying mat is disposed upon a countertop for placement of recently cleaned dishes, utensils, glassware, and other kitchenware or even produce for evaporation of any remaining rinse water. As shown in FIG. 1B, some drying mats may even include a conventional towel, or other absorption mat, to absorb water from the dishes, cookware, and glassware. Some drying mats are machine washable, whether in a dishwasher in the case of dish mats made from plastic or rubberized mat; or for washing a microfiber or cotton dish mat in a traditional clothing washer, for example.

Traditional drying mats in particular have many shortcomings. For example, such traditional drying mats often become saturated or otherwise prone to accumulating moisture and bacteria. Accumulation of moisture, saturation, and bacteria is particularly distasteful in the kitchen where food is prepared and cleanliness is a health necessity. Such accumulation of moisture, saturation, and bacteria is also visually unappealing for household members as well as guests. Traditional rubber mats and dish racks are also bulky and take up space when stored and are overall visually unappealing and cumbersome.

The subject matter claimed herein is not limited to embodiments that solve any disadvantages or that operate only in environments such as those described above. Rather, this background is only provided to illustrate one exemplary technology area where some embodiments described herein may be practiced.

### SUMMARY

In some embodiments, a drying implement, includes a first portion having a diatomaceous earth slab and a resilient slab covering, and a second portion that is coupled to the first panel. The resilient slab covering may include a mesh of openings that allow water from an article placed on the resilient slab covering to drip through the mesh of openings, onto the diatomaceous earth slab. The second panel may include a plurality of cross pieces that are overmolded with a resilient second covering.

In some embodiments, the resilient slab covering and the resilient second covering may be made from the same material. That material may include silicone. The silicone may have a durometer of between 30 and 60. The silicone may have a durometer of about 45.

The plurality of cross pieces may be made from aluminum or stainless steel. The plurality of cross pieces may be made from at least one of aluminum, another rigid material configured to resist rust or corrosion, a hard plastic or a polymer.

The second portion may be configured to be disposed over a sink while the first portion is disposed on a counter adjacent the sink. The second portion may be configured to facilitate rolling and unrolling.

The resilient slab covering may be configured to at least partially and removably encase the diatomaceous earth slab and may have a top surface, side edges and at least one of a bottom lip, a pocket or a strap. The bottom lip, pocket or strap may be configured to secure the resilient slab covering to the diatomaceous earth slab.

The top surface may include a mesh of ribs that form a plurality of apertures that are configured to allow liquid to drain from an object disposed on the resilient slab covering, through the apertures, to the diatomaceous earth slab. The mesh of ribs may define apertures having a width of about 0.75 inches.

### BRIEF DESCRIPTION OF THE DRAWINGS

To further clarify the above and other advantages and features, a more particular description will be rendered by reference to specific embodiments thereof which are illustrated in the appended drawings. It is appreciated that these drawings depict only typical embodiments and are therefore not to be considered limiting of its scope. Various embodiments will be described and explained with additional specificity and detail through the use of the accompanying drawings in which:

FIG. 1A illustrates conventional drying racks according to the prior art;

FIG. 1B illustrates a conventional drying mat in the form of a towel or other textile with dishes placed thereupon;

FIG. 2 illustrates a drying implement according to a first embodiment laid upon a countertop and adjacent to a sink;

FIG. 3 illustrates the drying implement with dishes disposed thereon;

FIG. 4 illustrates the drying implement being folded after use;

FIG. 5 illustrates the drying implement in the folded state both from a top view and a bottom view;

FIG. 6 illustrates the drying implement from a top and bottom view;

FIG. 7 illustrates the drying implement in an unassembled state;

FIG. 8 illustrates a second embodiment of a drying implement in a disassembled state;

FIG. 9 illustrates the second embodiment in a folded state;

FIG. 10 illustrates the second embodiment from a top view and a bottom view;

FIG. 11 shows the second embodiment from two perspective views;

FIG. 12 shows the second embodiment in a dis-assembled state; and

FIG. 13 provides a close-up of a joint between adjacent sections of the drying implement.

FIG. 14 illustrates exemplary dimensions of a drying implement.

FIG. 15A illustrates another exemplary drying implement.

FIG. 15B illustrates an exemplary application for the drying implement of FIG. 15A.

FIG. 16 is an exploded view of the exemplary drying element of FIGS. 15A and 15B.

FIG. 17 illustrates another exemplary drying implement.

FIG. 18 is an exploded view of the exemplary drying element of FIG. 17.

FIG. 19 illustrates an exemplary application for the drying implement of FIG. 17.

FIGS. 20A and 20B depict deployment of an exemplary drying implement.

### DETAILED DESCRIPTION

Embodiments of the drying implement disclosed herein can provide an adaptable, minimal, collapsible, dish drying pad. The drying implement is encased in woven, silicone protection for recently washed kitchenware placed thereon. Such drying implements include rapid absorption and drying diatomaceous earth panels that causes drain water to rapidly dissipate. This helps to prevent bacteria growth, by eliminating the moist environment where mold thrives. The mesh silicone layer or encasing keeps dishes protected and the kitchen looking fresh and modern. The drying implement shows various improvements for all types of drying jobs from dishes to produce. The drying implement folds upon its connected sections for smaller jobs, and for easy storage when not in use.

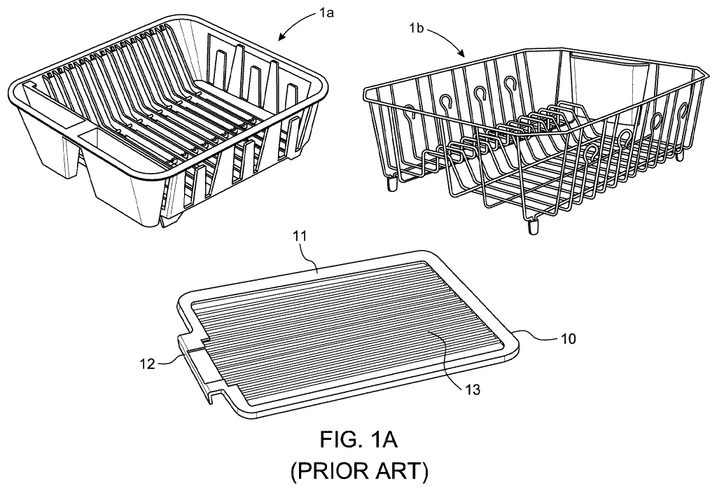

The drying implement is ideal for occasions when a full rack such as those discussed in the Background with reference to FIG. 1A is not needed but simply provides a sanitary space to dry your dishes while protecting the countertop. The foldable drying implements disclosed herein provide an adaptable and affordable drying system that instantly eliminates pooling water. A silicone wrapping helps promote 360 degree air flow while protecting delicate items according to some embodiments. When finished, the drying implement can be folded and stored in even a relatively small drawer or under the sink.

Several embodiments disclosed herein relate to improvements in countertop drying mats, arrangements, or pads referred to herein as drying implements. Such drying implements can be made from a multi-layer, composite, modular, or multi-part construction or assembly. The rapid-drying absorptive countertop drying implement can include multiple layers. A first layer of the drying implement can include a wicking absorption earth element layer. A second layer of the drying implement can include a flexible, resilient, porous, and/or connective layer.

The composite parts, elements, and wicking absorptive earth element portion(s) can be assembled together with the flexible, resilient, porous, web-like connective layer to create the combined advantages of the absorptive countertop drying implement disclosed herein. The assembled drying implements may also be disassembled in some embodiments such that one or more portions thereof may be independently cleaned and/or replaced. Moreover, one or more portions, or the assembled drying implement, can be collapsible, foldable, or otherwise reducible in size or shape for improved storage or confined use.

In some advantageous embodiments, the drying implement can be foldable and/or stackable. The drying implement can include two or more substantially rigid wicking absorptive earth element portions, also referred to as panels, joined together by one or more relatively flexible joints. The joints between the substantially rigid portions can allow for the rigid portions to remain connected to adjacent portions even though the portions are folded once upon another in a stack-like fashion.

When folded, the portions of the drying implement can be disposed upon each other such that they lie parallel and vertically layered each upon another portion of the drying implement. The layers may be sequentially joined so as to be connected on opposing ends from one inner section to adjacent exterior sections and any number of connect (able) sections may bed used.

The flexible joint can be a rubber connection between adjacent wicking absorptive earth element sections. According to some embodiments, the flexible portion can be made of a flexible and resilient molded rubber or silicone layer (e.g., food-grade silicone). The flexible portion can be molded to include a plurality of voids there through for allowing water to drip through the resilient portion and onto the one or more substantially rigid wicking absorption earth element portions or panels.

As previously discussed, the drying implement can include substantially rigid segments separated by flexible joints there between. The substantially rigid segments can be due to substantially rigid absorptive diatomaceous earth element panels inserted into, attached to, or affixed to segments of the substantially flexible portion. The substantially flexible portion can be made from a cushioning silicone pad that slips around the panels of substantially rigid earth element and holds the panels together. The cushioning attributes of the flexible portion can cushion dishes and glassware placed therein and also prevent the substantially rigid panels from scratching or wearing the utensils and other kitchenware. In between the panels is one or more joint formed in the silicone pad that holds one panel to one or more adjacent panels of absorptive earth elements, such as panels made of diatomaceous earth.

Rapidly wicking and drying earth portions can include the material called diatomaceous earth. Diatomaceous earth—also known as D.E., diatomite, or kieselgur/kieselguhr—is a naturally occurring, soft, siliceous sedimentary rock that is traditionally easily crumbled into a fine white to off-white powder. It has a particle size ranging from less than 3 μm to more than 1 mm, but typically 10 to 200 μm. Depending on the granularity, this powder can have an abrasive feel, similar to pumice powder, and has a low density as a result of its high porosity. The typical chemical composition of oven-dried diatomaceous earth is 80-90% silica, with 2-4% alumina (attributed mostly to clay minerals) and 0.5-2% iron oxide.

Diatomaceous earth consists of fossilized remains of diatoms, a type of hard-shelled protist (chrysophytes). As disclosed herein the layer or component of diatomaceous earth of the mat is used as an absorbent and rapid evaporator for liquids. The thermal properties of diatomaceous earth also enable it to be used as the barrier material according to several embodiments disclosed herein.

For example, several embodiments disclosed herein include a diatomaceous earth component forming a part of the countertop drying mat. In several embodiments, the diatomaceous earth component can be a lower layer disposed underneath an upper layer having a pours, voids, slots, a web-like configuration, or other passages for liquid to flow through and be absorbed by the diatomaceous earth layer. The placement of the diatomaceous earth layer or component immediately below the mat upon which dishes, utensils, and glassware is placed allows for the diatomaceous earth to rapidly wick and absorb the moisture from the dishes, glassware, and utensils thereby rapidly removing saturation of water from the drying environment immediately adjacent the dishes, utensils and glassware. Once absorbed by the diatomaceous earth layer, the repeated saturation of the drain mat is more rapidly evaporated and dried as compared to traditional drying mats and other drain assemblies. The pours, voids, slots, and other passages through the resilient polymer portion also allows for circulation of air under the dishware, glasses, utensils, and any other clean yet wet implement for evaporation of water therefrom.

According to some embodiments, the resilient layer can be referred to as having a flexible web portion including a plurality of ribs separated by voids and passages there through so as to allow water to drip onto the substantially rigid diatomaceous earth panels. The outer periphery of the web portion can include a series of lower extending ribs that extend below the resilient layer and around the periphery of the panels when inserted therein. The ribs can include vertical locating protrusions for securing the panels of diatomaceous earth therein. Moreover, one or more straps or end caps can be disposed on an underside of the resilient layer for further securing the panels of absorptive earth elements to the underside of the resilient web layer.

The bottom side of the flexible layer can wrap around the diatomaceous earth panels and have protrusions or molded legs extending therefrom so as to lift the bottom of the implement above a countertop providing for additional circulation underneath the implement. This nearly 360 degree exposure of the diatomaceous earth panels provided for even more rapid evaporation of drain water absorbed the diatomaceous earth panels.

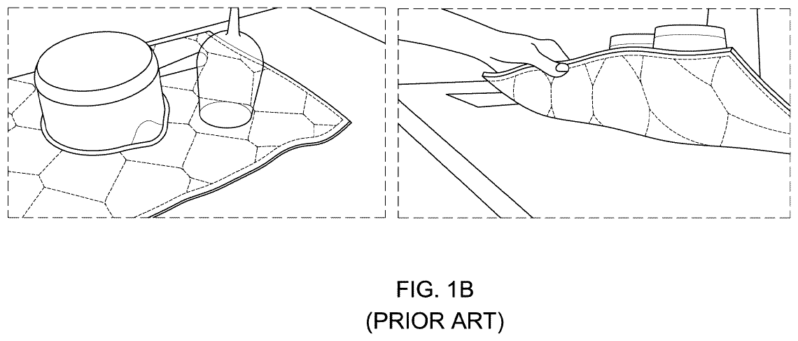

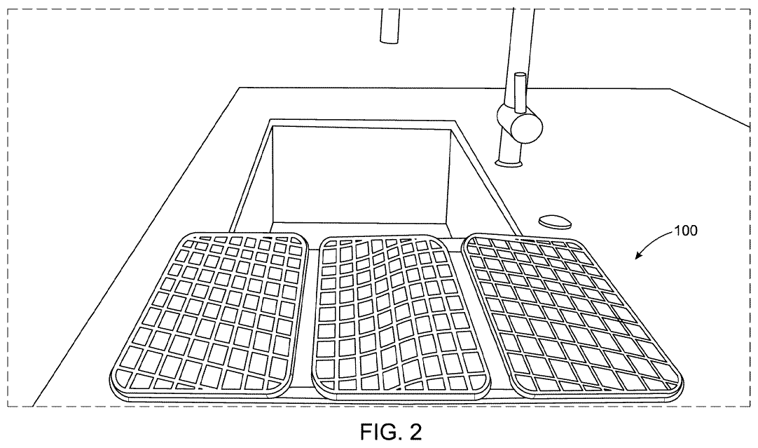

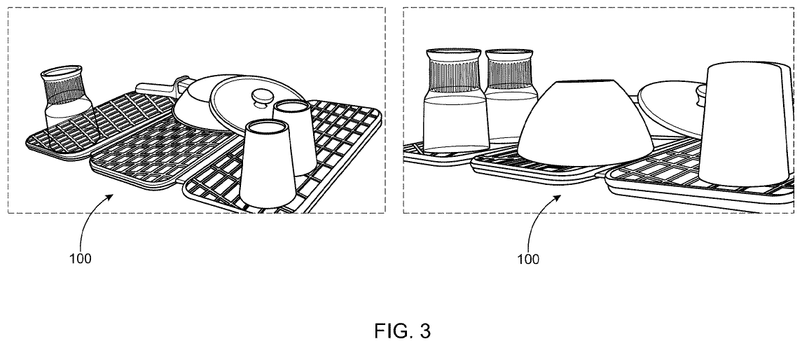

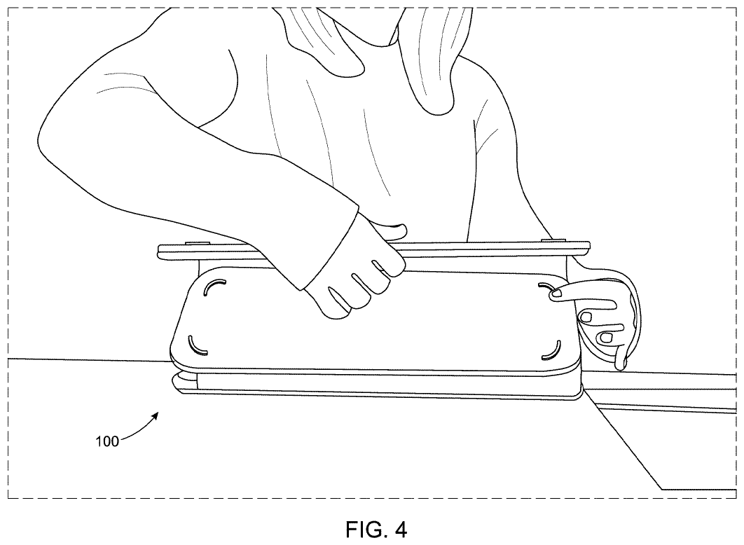

Referring to FIG. 2, an example of a drying implement 100 is shown. The drying implement 100 is in an unfolded state and placed proximate to sink. Referring to FIG. 3 the drying implement 100 is shown with various dishes placed thereon for drying. And, FIG. 4 shows the drying implement 100 being folded into a compact configuration shown in FIG. 5 from both a top and bottom perspective. As can be appreciated by a comparison of FIGS. 2-5 the utility of the foldable drying implement 100 is drastically increased due to its ability to be quickly used to absorb the drain water from the dishes while be versatile in the way it is foldable to a collapsed position.

FIG. 4 illustrates a fold pattern where one side panel is folded inside of the opposition side panel and on top of the center side panel. FIG. 5 illustrates an embodiment where the panels of the drying implement 100 are folded in a “Z” folding pattern where a center panel is folded upon a left side panel and a right side panel is folded over the center panel.

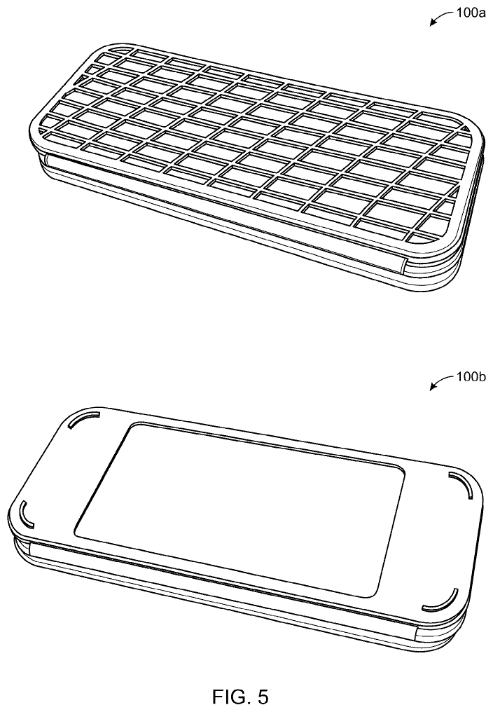

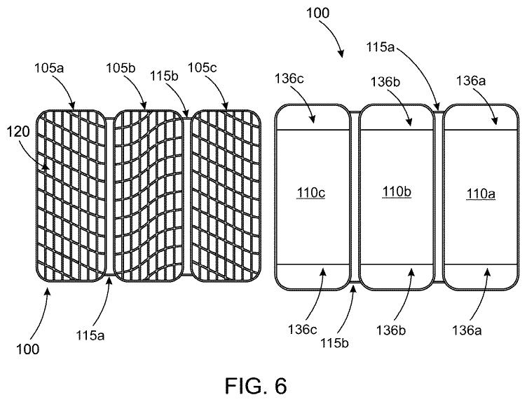

FIG. 6 illustrates the first embodiment of the drying implement 100 including a substantially resilient and flexible layer 105 and a plurality of substantially rigid absorption layers in the form of one or more absorption panels 110. FIG. 7 illustrates the drying implement 100 with the panels 110 disassembled from the flexible layer 105. As illustrated in FIGS. 6 and 7, the drying implement 100 can include three sections including a first section 105a of the resilient flexible layer 105, a second section 105b of the resilient flexible layer 105, and a third section 105c of the resilient flexible layer. Corresponding to the sections of the resilient flexible layer 105, the substantially rigid absorptive layer 110 can include three sections including a first section panel 110a of the absorptive layer 110, a second section panel 110b of the absorptive layer 110, and a third section panel 110c of the absorptive layer 110.

The resilient layer 105 can be formed of a molded polymer, such as a compression molded or liquid silicon molded silicone material so as to protect the kitchenware placed thereon. In some embodiments, LSR molding results in less flashing of material especially in the locations of voids 120, for example. The resilient layer 105 can be divided into sections connected by one or more flexible and foldable regions 115 there between. For example, as shown in FIG. 6, the three sections 105a, 105b, and 105c of the resilient layer 105 and be joint to adjacent sections by a connective joint 115. As shown in FIGS. 6 and 7, the first section 110a of the resilient flexible layer 110 is connected to the second section 110b by a first flexible joint 115 of the first flexible layer 110. The second section 110b is connected to the third section 110c of the flexible layer 110 by a second flexible joint 115.

The resilient layer 105 can include upper and lower pockets 136 for securing end portions of the lower layer 110 to the upper layer 105. The pairs of end pockets 136a, 136b, and 136c secure an outer periphery of the individual absorptive panels 110a-c respectively. And, the individual absorptive panels 210a-c are inserted into and held by the end pockets 136a, 136b, and 136c onto a bottom of the resilient upper layer 205. The pockets 236 can be formed integral and molded with the upper layer of the resilient layer 205.

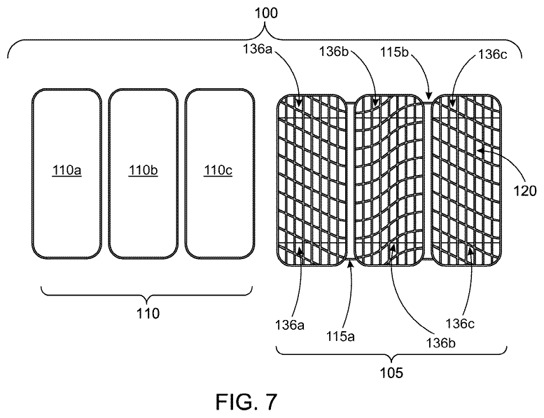

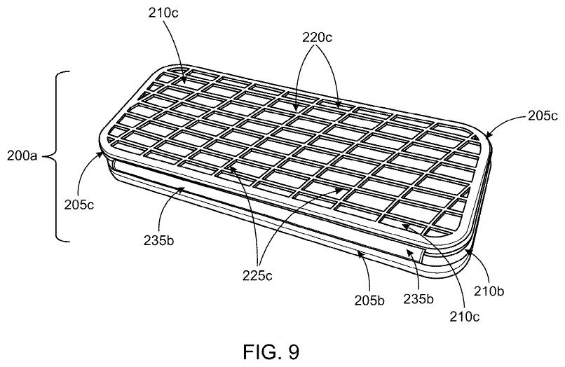

Referring to FIGS. 8-12 a second embodiment of a drying implement 200 is shown. The drying implement 200 includes a plurality of absorption panels 205 and a flexible layer 210 having a plurality of sections corresponding to the absorption panel. The sections 205a-c of the resilient layer 205 can include a plurality of voids 220, pores, perforations, or slots that are molded, cut, or otherwise formed there through allow for water to drip through the sections of the resilient layer 205a-c to the panels 210a-c of substantially rigid absorption material 210. The size of the voids 220a-c corresponding to sections 205a-c can be selected for allowing for the moisture to drip onto the absorptive layer 210. For example, the sections 205a-c of the resilient flexible layer 205 can have ribs or partitions 225 separating and defining the voids 220. The arrays of ribs or partitions 225 can extend along an X direction and Y direction as shown in FIG. 10. The ribs or partitions 125 can also have a depth or thickness extending in the Z direction.

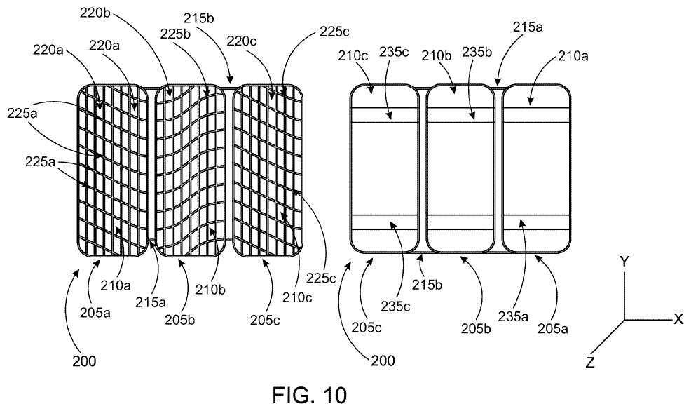

Referring to FIGS. 10, the resilient layer 205 can include lower circumferential end caps 236 according to the second embodiment for securing end portions of the absorptive panels 210 to the flexible upper layer 205. As shown in FIG. 11, lips 230a-c secure an outer periphery of the individual absorptive panels 210a-c respectively. And, the individual absorptive panels 210a-c are inserted into and held by the straps 135a-c in the second embodiment and end caps or sleeves 126 according to the first embodiment onto a bottom of the resilient upper layer 205 and 105 respectively. According to the embodiment shown in FIGS. 6 and 10, end caps 136 and the straps 235 can be formed integral and molded with the upper layer of the resilient layer 105 and 205, respectively.

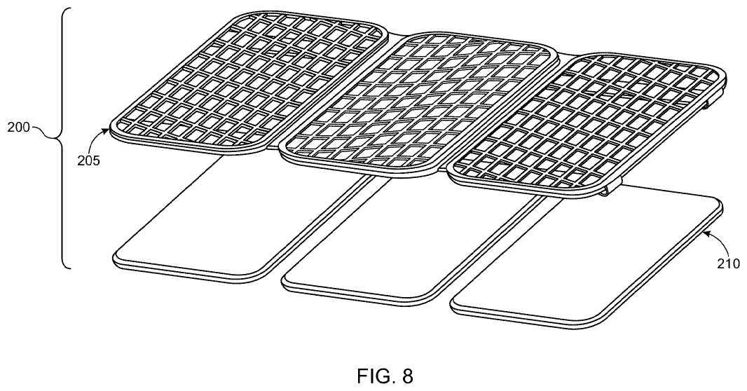

Referring to FIG. 9, the second embodiment of the drying implement 100, for example for drying kitchenware, is shown in a folded state. The third substantially resilient and flexible layer 205c is shown as a top layer folded upon a second layer 205b of the drying implement 200. The third panel 225c is shown retained by the lips of the third section 205c of the substantially resilient layer 205. The first and second sections 205b and 205c are connected by joints 215b as shown in FIG. 11. The ribs 225c and voids 220c are of the third section 205c of the resilient flexible layer 205 are shown. The drying implement 200 can be folded into the state shown in FIG. 9 for storage and can be unfolded back into the state shown in FIG. 10 for use. The folded state of the drying implement for kitchenware shown in FIG. 8 can also be used for drying kitchenware.

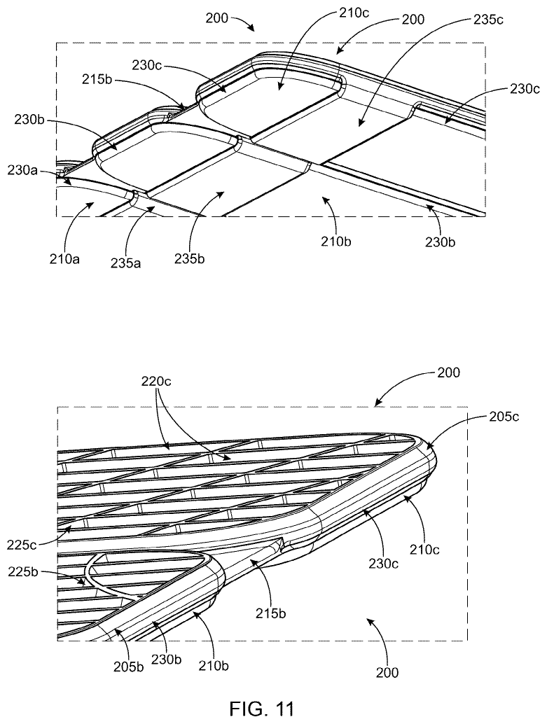

FIG. 12 illustrates the substantially flexible layer 205 disassembled from the substantially absorptive layer 210 of the drying implement 200. A shown, the absorptive sections 205a, 205b, and 205c in the form of substantially rigid panels comprising diatomaceous earth can be assembled with and dis-assembled from the corresponding sections 205a, 205b, and 205c of the substantially rigid layer 205 comprising a polymer material such as molded silicone.

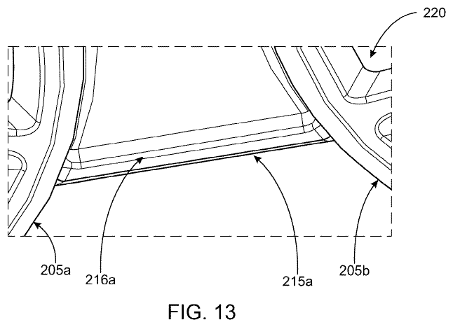

Assembly of the panels 205a, 205b and 205c can include insertion of the panels 205a, 205b and 205c into the respective sleeves 235a, 235B, and 235C of the respective sections 205a, 205b, and 205c of the substantially resilient layer 205. The sections 205a, 105b, and 105c being connected by the joints 115a and 115b. Some examples of materials and dimensions of a drying implement 100 and 200 including a substantially resilient and flexible layer 2 and an absorption layer 1 according to an embodiment are illustrated in FIG. 14. Referring again to FIG. 12, the second example of the drying implement 200 is shown including a substantially resilient and flexible layer 205 and a plurality of substantially rigid absorption panels 210.

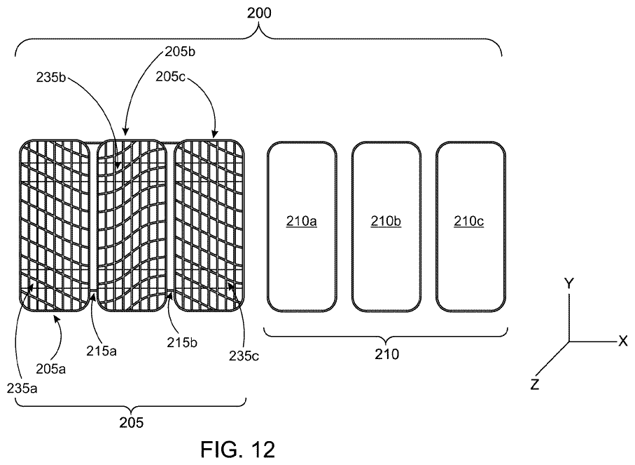

The second embodiment 200 illustrated has the size and shape of the joints 215 recessed from just one of the flexible layer 205 as further illustrated in FIG. 13. The resilient layer 205 can be formed of a molded polymer, such as a compression molded or LSR silicone material and can be divided into sections connected by the one or more flexible and foldable region 215 there between. As previously discussed, in some embodiments, LSR molding results in less flashing of material especially in the locations of voids 220 and 220, for example. For example, as shown in FIG. 12, the three sections 205a, 205b, and 205c of the resilient layer 105 be connected to adjacent sections by a connective joint 115. As shown in FIG. 12, the first section 205a of the resilient flexible layer 205 is connected to the second section 205b by a first flexible joint 215a of the first flexible layer 205. The second section 205b is connected to the third section 205C of the flexible layer 205 by a second flexible joint 215b. Example dimensions can include: Length: 19.91 inches/50.57 cm, Width 15.21 inches/38.63 cm, Height: 0.52 inches/1.32 cm. Additional dimensions are illustrated in FIG. 14. A silicone pad that is disposed around panels may preferably have a durometer of about 45. In other embodiments, the durometer may be within range of about 30 to about 60. Thickness of panels can be 0.35 inches radius 0.12 inches on ends. Length can be about 20 inches and width is about 15.25 inches. Each panel can be about 15 inches in width and 6 inches in length as shown in some embodiments. Three panels and one silicone rubber pad may be used as shown, however according to other embodiments, a single panel and silicone rubber panel or any number thereof may be implemented.

Referring to FIG. 13, a close-up view of joint 215a is shown having an upwardly extending lip 216a for retaining water upon the joint 215a and substantially preventing the water from spilling onto a countertop disposed there under during use. The lip remains foldable at the joint as previously discussed and shown and water is allowed to dry on the silicone joint in such embodiments.

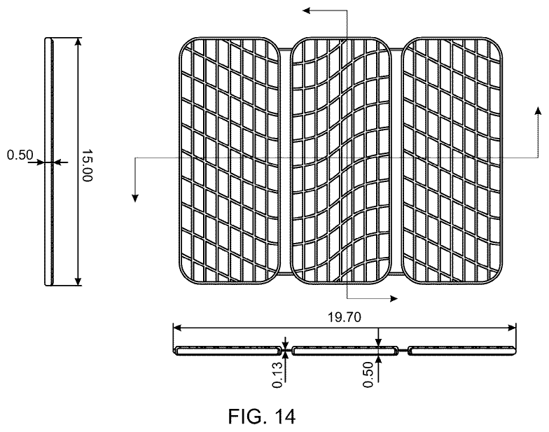

FIGS. 15A and 15B illustrate another embodiment of a drying element 1501 configured for use over a sink. As shown, the drying element 1501 is configured as a tri-fold design comprising three panels 1504A, 1504B and 1504C. The panels 1504A, 1504B and 1504C may be configured such that the drying element 1501 can be folded in a “Z” configuration, thereby having only one-third of the footprint that the drying element 1501 occupies when fully “unfolded.”

In some embodiments, panel 1504A may comprise a mat configured to support dishes (not shown) over a countertop 1507 (see FIG. 15B). Panel 1504A may include a slab 1510 of diatomaceous earth-based material, with a silicone (or other waterproof, resilient material) over-mold 1513. The over-mold material may provide cushioning for dishes or other items that may be placed thereon. The over-mold material may further include a mesh of openings that allow water dripping from any such dishes or other items onto the slab of diatomaceous earth material, which, in turn, may be configured to absorb such water.

In some embodiments, panels 1504B and 1504C may comprise side rails 1516 and a plurality of cross pieces 1519. Other than the cross pieces 1519, the panels 1504B and 1504C may be open in the middle, such that these panels 1504A and 1504B can be positioned over a sink 1522, as shown in FIG. 15B. In such embodiments, the drying rack 1501 may provide a first section, corresponding to panel 1504A, on which dishes or other articles may be placed to drip-dry onto the diatomaceous earth slab 1510; and second and third sections, corresponding to panels 1504B and 1504C, on which dishes or other articles may be placed to drip-dry directly over the sink 1522.

In some embodiments, the panels 1504B and 1504C may facilitate drip-drying of food items, such as, for example, fruits and vegetables that have been washed and otherwise processed (e.g., cut, seasoned, etc.). In such embodiments, the drying rack 1501 may provide stylish functionality for various kitchen tasks that are commonly performed near a sink 1522.

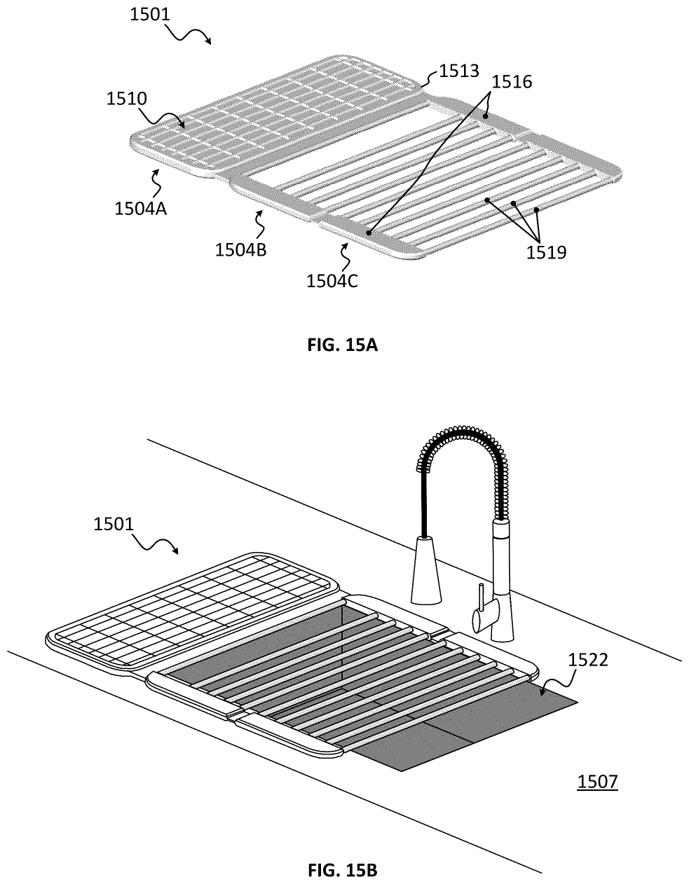

FIG. 16 illustrates an exploded view of the exemplary drying element 1501 shown in FIGS. 15A and 15B. As shown, the cross pieces 1519 may comprise individual elements of metal (e.g., aluminum, stainless steel or other light but rigid material configured to resist rust or corrosion) or other material (e.g., a hard plastic or polymer). The over-molded material 1513 is shown as a unitary element, but in some embodiments, individual components (e.g., the cross-pieces 1519) may be individually over-molded or coated. In some embodiments, the over-molding material 1513 itself may comprise silicone or another resilient material, that, in some embodiments, provides some cushioning for articles placed thereon.

In some embodiments, internal rails (not shown) may be provided to support and retain the cross pieces 1519, and such internal rails and cross pieces 1519 may be over-molded together. In other embodiments, each individual cross piece 1519 is over-molded or coated and configured to be disposed into a relatively more rigid portion of the side rails 1516.

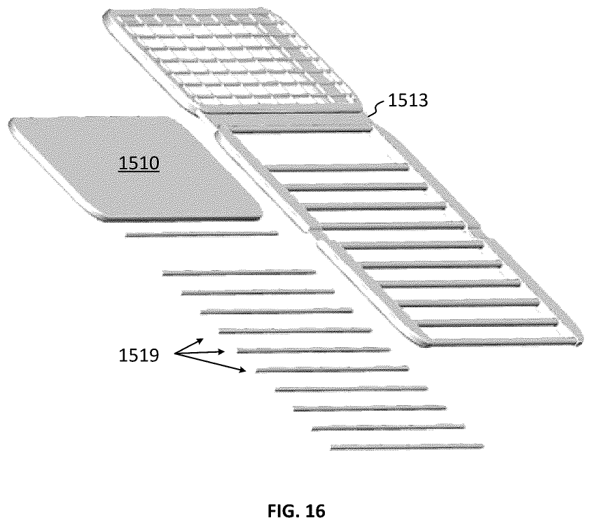

FIG. 17 illustrates another exemplary drying element 1701. As shown, the drying element 1701 is configured with two panels 1704A and 1704B. The panels 1704A and 1704B may be configured such that the drying element 1701 can be folded, thereby having only a fraction of the footprint that the drying element 101 occupies when fully “unfolded.”

In some embodiments, panel 1704A may comprise a mat configured to support dishes (not shown) over a countertop. Panel 1704A may include a slab 1710 of diatomaceous earth-based material, with a silicone (or other waterproof, resilient material) over-mold 1713. The over-mold material may provide cushioning for dishes or other items that may be placed thereon. The over-mold material may further include a mesh of openings that allow water dripping from any such dishes or other items onto the slab of diatomaceous earth material, which, in turn, may be configured to absorb such water.

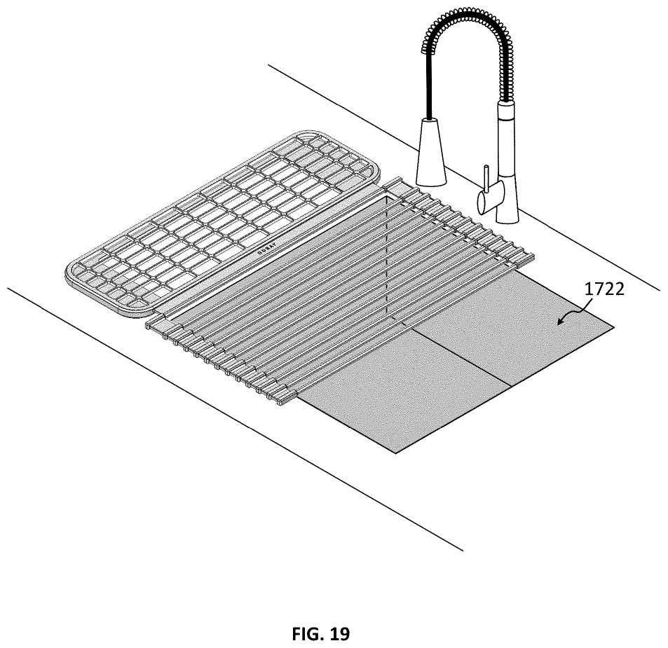

In some embodiments, panel 1704B may comprise side rails 1716 and a plurality of cross pieces 1719. Other than the cross pieces 1719, the panel 1704B may be open in the middle, such that this panel 1704B can be positioned over a sink, as shown in FIG. 19. In such embodiments, the drying rack 1701 may provide a first section, corresponding to panel 1704A, on which dishes or other articles may be placed to drip-dry onto the diatomaceous earth slab 1710; and a second section, corresponding to panel 1704B, on which dishes or other articles may be placed to drip-dry directly over a sink 1722.

In some embodiments, the panel 1704B may facilitate drip-drying of food items, such as, for example, fruits and vegetables that have been washed and otherwise processed (e.g., cut, seasoned, etc.). In such embodiments, the drying rack 1701 may provide stylish functionality for various kitchen tasks that are commonly performed near a sink.

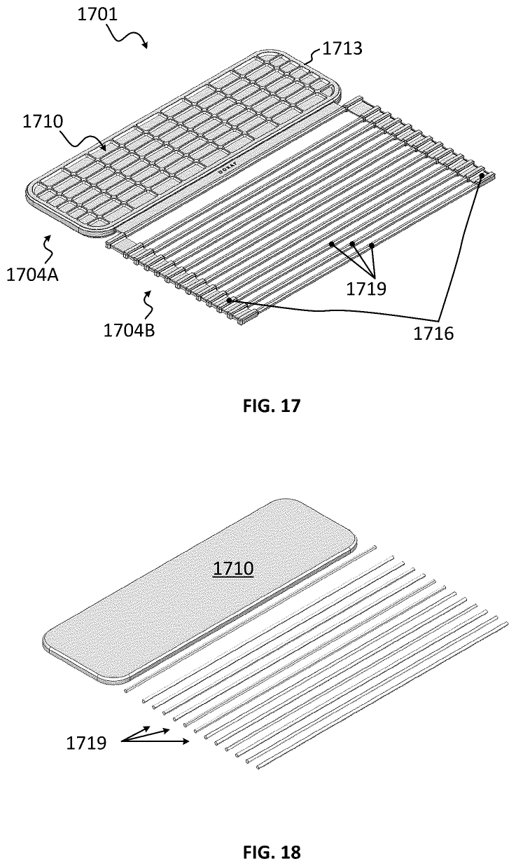

FIG. 18 illustrates an exploded view of the exemplary drying element 1701 shown in FIG. 17. As shown, the cross pieces 1719 may comprise individual elements of metal (e.g., aluminum or other light but rigid material configured to resist rust or corrosion) or other material (e.g., a hard plastic or polymer). The over-molded material 1713 is shown as a unitary element, but in some embodiments, individual components (e.g., the cross-pieces 1719) may be individually over-molded or coated. In some embodiments, the over-molding material 1713 itself may comprise silicone or another resilient material, that, in some embodiments, provides some cushioning for articles placed thereon.

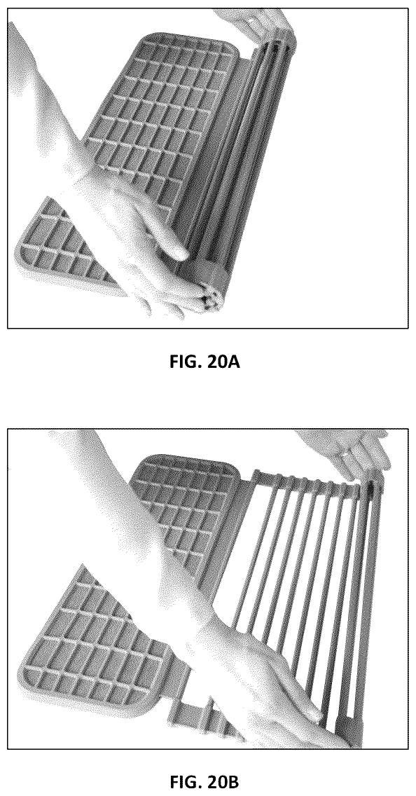

In some embodiments, internal rails (not shown) may be provided to support and retain the cross pieces 1719, and such internal rails and cross pieces 1719 may be over-molded together. In other embodiments, each individual cross piece 1719 is over-molded or coated and configured to be disposed into a relatively more rigid portion of the side rails 1716. In still other embodiments, no separate stiffening material is provided for the side rails 1716; rather, the side rails 1716 may be made entirely of flexible, resilient overmolding material (e.g., silicone), which may enable the panel 1704B to be rolled and unrolled, as depicted in FIGS. 20A and 20B. In some embodiments, the individual cross pieces 1719 may be overmolded; in other embodiments, the cross pieces 1719 are only overmolded at their ends to retain them in the side rails 1716; in still other embodiments, the side rails 1716 (flexible and “rollable,” or otherwise) are molded separately from the cross pieces 1719, which cross pieces 1719 may then be inserted into the side rails 1716 during a separate manufacturing operation.

Thus, the embodiments disclosed herein provided rapid drying of dishes or other articles that are subjected to repeated saturation or wet environments while providing for a resilient soft surface for kitchenware as well as replaceable and collapsible components thereof.

One skilled in the art will appreciate that, for this and other processes and methods disclosed herein, the functions performed in the processes and methods may be implemented in differing order. Moreover, the structures of apparatus may be reorganized or variated to accomplish a given feature or function. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It is understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). As used herein, “about” or “approximately” or “substantially” may mean within 1%, or 5%, or 10%, or 20%, or 50%, or 100% of a nominal value. Other variations are contemplated.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, quadrants, thirds, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above.

Various embodiments may take other specific forms without departing from their spirit or essential characteristics. Some embodiments may include one, two, three or more panels. Some panels may include diatomaceous earth; other panels may include only cross pieces. Panels that include cross pieces may be configured to be disposed over a sink. Some such panels may be rigid, while others may be configured to be rolled and unrolled. The described embodiments are to be considered in all respects only as illustrative and not restrictive. The scope is, therefore, indicated by the appended claims rather than by the foregoing description. All changes which come within the meaning and range of equivalency of the claims are to be embraced within their scope.

What is claimed is:

1. A drying implement, comprising:
a first panel that comprises a diatomaceous earth slab and a resilient slab covering, the resilient slab covering comprising a mesh of openings that allow water from an article placed on the resilient slab covering to drip through the mesh of openings, onto the diatomaceous earth slab; and
a second panel that is coupled to the first panel, the second panel comprising a plurality of cross pieces that are overmolded with a resilient second covering.

2. The drying implement of claim 1, wherein the resilient slab covering and the resilient second covering comprise the same material.

3. The drying implement of claim 2, wherein the same material comprises silicone.

4. The drying implement of claim 1, wherein the plurality of cross pieces comprises aluminum or stainless steel.

5. The drying implement of claim 1, wherein the plurality of cross pieces comprises at least one of aluminum, another rigid material configured to resist rust or corrosion, a hard plastic or a polymer.

6. The drying implement of claim 1, wherein the second panel is configured to be disposed over a sink while the first panel is disposed on a counter adjacent the sink.

7. A drying implement, comprising:
a first portion that comprises a diatomaceous earth slab and a resilient slab covering, the resilient slab covering comprising a mesh of openings that allow water from an article placed on the resilient slab covering to drip through the mesh of openings, onto the diatomaceous earth slab; and
a second portion that is coupled to the first portion, the second portion comprising a plurality of cross pieces that are overmolded with a resilient second covering; wherein the second portion is configured to facilitate rolling and unrolling.

8. The drying implement of claim 7, wherein the resilient slab covering is configured to at least partially and removably encase the diatomaceous earth slab; and has a top surface, side edges and at least one of a bottom lip, a pocket or a strap; and wherein the at least one of the bottom lip, the pocket or the strap is configured to secure the resilient slab covering to the diatomaceous earth slab.

9. The drying implement of claim 8, wherein the top surface comprises a mesh of ribs that form a plurality of apertures that are configured to allow liquid to drain from an object disposed on the resilient slab covering, through the apertures, to the diatomaceous earth slab.

10. The drying implement of claim 9, wherein the mesh of ribs defines apertures having a width of about 0.75 inches.

11. The drying implement of claim 7, wherein the resilient slab covering and the resilient second covering are formed from a molded polymer material.

12. The drying implement of claim 11, wherein the molded polymer material comprises a molded silicone material.

13. The drying implement of claim 12, wherein the molded silicone material has a durometer of between 30 and 60.

14. The drying implement of claim 12, wherein the molded silicone material has a durometer of about 45.
